(19) United States
(12) Patent Application Publication
(10) Pub. No.: US 2011/0098951 A1
(43) Pub. Date: Apr. 28, 2011

(54) ARRANGEMENT AND METHOD FOR GENERATING A FAULT SIGNAL

(75) Inventor: Andreas Jurisch, Schwante (DE)

(73) Assignee: SIEMENS AKTIENGESELLSCHAFT, MÜNCHEN (DE)

(21) Appl. No.: 13/000,084

(22) PCT Filed: Jun. 18, 2008
(86) PCT No.: PCT/EP2008/005212

§ 371 Date: Dec. 20, 2010

(51) Int. Cl. G01R 31/02; G06F 19/00; H02H 1/00

(52) U.S. Cl. 702/58; 324/509; 361/42

(57) ABSTRACT

A method for generating an error signal that characterizes a ground fault on a conductor between two conductor ends. A differential value is formed and the error signal is generated when the differential value meets a prescribed initiating condition. A first comparison value is determined for a selectable location on the conductor using at least one measured current and voltage value taken at a prescribed measurement point in time at one end of the conductor. The comparison value indicates the current or the voltage that should flow or be present at the selectable location in an error-free state. A second comparison value is determined for the selectable location on the conductor using at least one measured current or voltage value, taken at the prescribed measurement point in time at the other end of the conductor. The two comparison values are subjected to difference formation, forming the differential value.

The invention relates to a method having the features according to the precharacterizing clause of claim 1.

In order to monitor faults in electrical power supply lines, use is normally made of electrical protection devices which use specific protection algorithms to decide whether there is a fault on the electrical power transmission line. Suitable countermeasures are automatically taken if a fault is detected; circuit-breakers are usually opened in order to isolate the fault. A protection algorithm often used in this connection is so-called differential protection.

In a differential protection method, an electrical differential protection device is provided at each end of a monitored line section of the electrical power supply line, which differential protection device uses current transformers fitted to the respective ends of the line section to record current measured values which indicate the current flowing in the line section. The current measured values may be, for example, current vector measured values which provide a higher degree of accuracy than simple root-mean-square values since they include information relating to the amplitude and phase angle of the measured current. The recorded current measured values are interchanged via a communication line between the differential protection devices and are compared with one another. When there are no faults, the current which flows into the line section is the same as that which flows out of said section again at a particular point in time. If the difference is consequently formed between the magnitudes of the current measured values respectively measured at the ends of the line section, a value close to zero should result when there are no faults. However, if there is a fault in the line section, a so-called fault current flows via the fault point and the magnitudes of the current measured values simultaneously recorded at the ends no longer correspond. A difference between the current measured values which is above a particular tripping value consequently results, with the result that the differential protection devices detect a fault in the line section.

The phase affected by the short circuit can then be switched off by means of circuit-breakers at the ends of the line section, which circuit-breakers are connected to the differential protection devices. For this purpose, the differential protection devices generate, as a fault signal, a so-called TRIP signal (tripping signal) which causes the connected circuit-breakers to open their switching contacts, as a result of which the faulty part of the line section is isolated from the rest of the power supply line.

The invention is based on the object of further improving protection methods of the type described at the outset and increasing their protective effect.

This object is achieved, according to the invention, by a method having the features of patent claim 1. Advantageous refinements of the method are specified in subclaims.

The invention provides for a first comparison value to be determined for a selectable location on the line using at least one current measured value and one voltage measured value recorded at one end of the line at a predefined measuring time, said first comparison value indicating the current or voltage which ought to flow or be present at the selectable location in the fault-free state, for a second comparison value to be determined for the selectable location on the line using at least one current or voltage measured value recorded at the other end of the line at the predefined measuring time, said second comparison value indicating the current or voltage which ought to flow or be present at the selectable location in the fault-free state, and for the two comparison values to be subtracted so as to form the difference value.

An important advantage of the method according to the invention can be seen in the fact that measurement errors on account of an excessively large distance between the two ends of the line are avoided in said method. This can be specifically attributed to the fact that, in contrast to previously known methods, measured values which relate to the same measuring point are compared rather than measured values which relate to different points of the line. This is because, particularly in the case of a large distance between the two ends of the line, the problem of, for example, the currents at the two ends of the line differing even though a fault has not occurred at all may arise. This is where the invention begins in that only measured values for a single location are taken into account, according to the invention, in order to compare the measured values and to generate the fault signal, the measured values for this location being determined on the basis of the measurement results at the ends of the line.

The comparison values can be formed on the basis of time or frequency, for example using current and/or voltage vectors. If the comparison values are calculated using vectors, it is considered to be advantageous if the vectors are subjected to a Clarke transformation and the comparison values are formed using the vectors which have been subjected to the Clarke transformation.

If a location between the two ends of the line is selected as the selectable location, the second comparison value is preferably determined using both a current measured value recorded at the other end of the line and a voltage measured value recorded at the other end of the line at the predefined measuring time.

If the other end of the line is selected as the selectable location, the current or voltage measured value at the other end of the line is preferably used directly as the second comparison value.

The two comparison values are determined in a particularly simple and thus advantageous manner taking into account the telegraph equation which describes the propagation of electromagnetic waves on lines.

One particularly preferred refinement of the method provides for the propagation constant and the characteristic impedance of the line to be determined in a fault-free parameter learning phase in order to use the telegraph equation.

It is particularly advantageous if the propagation constant and the characteristic impedance are determined during the parameter learning phase using an estimation method, the magnitude and the phase of the propagation constant and of the characteristic impedance of the line being adapted during the estimation method in such a manner that the difference between the first comparison value and the second comparison value is minimal.

A least-squares estimation method, a Kalman filter algorithm or an ARMAX estimation method is preferably used as the estimation method.

If the other end of the line is selected as the selectable location, the first and second comparison values can be determined, for example, according to:

VI1=(1/Z)*sin h(γ*L)*Ua+cos h(γ*L)*Ia

VI2=Ib

where Z denotes the characteristic impedance of the line, γ denotes the propagation constant on the line, L denotes the length of the line, Ua denotes the voltage measured value recorded at one end of the line, Ia denotes the current measured value recorded at one end of the line, Ib denotes the current measured value recorded at the other end of the line, VI1 denotes the first comparison value and VI2 denotes the second comparison value. In this procedure, comparison current values are thus formed as comparison values.

Alternatively, comparison voltage values may also be formed as comparison values, for example according to:

VU1=Ua*cos h(γ*L)+Z*Ia sin h(γ*L)

VU2=Ub

where Z denotes the characteristic impedance of the line, γ denotes the propagation constant on the line, L denotes the length of the line, Ua denotes the voltage measured value recorded at one end of the line, Ia denotes the current measured value recorded at one end of the line, Ub denotes the voltage measured value recorded at the other end of the line, VU1 denotes the first comparison value and VU2 denotes the second comparison value.

If a location between one end of the line and the other end of the line is selected as the selectable location, the first and second comparison values can be determined in the form of comparison current values, preferably according to:

VI1=(1/Z)*sin h(γ*l)*Ua+cos h(γ*l)*Ia

VI2=(1/Z)*sin h(γ*(L−l))*Ub+cos h(γ*(L−l))*Ib

where Z denotes the characteristic impedance of the line, γ denotes the propagation constant on the line, L denotes the length of the line, l denotes the length of the line between the selectable location and one end of the line, Ua denotes the voltage measured value recorded at one end of the line, Ia denotes the current measured value recorded at one end of the line, Ub denotes the voltage measured value recorded at the other end of the line, Ib denotes the current measured value recorded at the other end of the line, VI1 denotes the first comparison value and VI2 denotes the second comparison value. Alternatively, comparison voltage values can also be formed, preferably according to:

VU1=Ua*cos h(γ*l)+Z*Ia sin h(γ*l)

VU2=Ub*cos h(γ*(L−l))+Z*Ib sin h(γ*(L−l))

where Z denotes the characteristic impedance of the line, γ denotes the propagation constant on the line, L denotes the length of the line, l denotes the length of the line between the selectable location and one end of the line, Ua denotes the voltage measured value recorded at one end of the line, Ia denotes the current measured value recorded at one end of the line, Ub denotes the voltage measured value recorded at the other end of the line, Ib denotes the current measured value recorded at the other end of the line, VU1 denotes the first comparison value and VU2 denotes the second comparison value.

If the comparison values are formed on the basis of time, the summands can be converted into IIR filters in order to form the comparison current values. In order to explain this variant of the method, the equation

VI1=(1/Z)*sin h(γ*l)*Ua+cos h(γ*l)*Ia

which has already been described is used by way of example below. This equation can be transformed by combining the constant complex transfer functions, for example, as follows:

VI1(jω)=G1(jω)*Ua(jω)+G2(jω)*Ia(jω)

where:

G1(jω)=(1/Z)*sin h(γ*l)

G2(jω)=cos h(γ*l).

Inverse transformation of this equation into time-discrete sequences of samples (z domain) results in:

VI1(z)=G1(z)*Ua(z)+G2(z)*Ia(z).

The comparison value can thus also be determined in this manner as a time-discrete sample from the samples of the current and voltage measured values.

### THE LITERATURE CITATIONS

[1] Levi, E. C., “Complex-Curve Fitting”, IRE Trans. on Automatic Control, Vol. AC-4 (1959), pp. 37-44 and
[2] Dennis, J. E., Jr., and R. B. Schnabel, “Numerical Methods for Unconstrained Optimization and Nonlinear Equations”, Prentice-Hall, 1983
   describe, for example, methods which allow direct design of IIR filters for the transfer functions G1(z) and G2(z) from the transfer functions G1(jω) and G2(jω). For this purpose, use may be made of, for example, the MATLAB function invfreqz( ) which implements these methods.

In order to make it possible to directly evaluate the measured values, it is considered to be advantageous if the current and voltage at the two ends of the line are measured in a synchronized manner.

Alternatively, the current and voltage measured values at the two ends of the line can also be measured in an unsynchronized manner; in such a case, it is considered to be advantageous if the current and voltage measured values are provided with a time stamp which indicates the respective recording time of the measured values, and the current and voltage measured values of the two ends of the line are computationally synchronized using their respective recording time, and current and voltage measured values based on the predefined measuring time are formed.

The invention also relates to an arrangement for generating a fault signal which indicates a ground fault on a line between a first end of the line and a second end of the line.

According to the invention, the arrangement has: a first measuring device at the first end of the line, a second measuring device at the second end of the line, and an evaluation device which is connected to the two measuring devices and is suitable for carrying out a method as described above using the measured values from the two measuring devices.

The evaluation device is preferably formed by a programmed data processing system or data processing device.

The evaluation device may be arranged, for example, in a central device to which the two measuring devices are connected. Alternatively, the two measuring devices may be connected to one another, the evaluation device being implemented in one of the measuring devices.

The invention also relates to a field device, in particular a protection device, for connection to one end of an electrical line and for detecting a ground fault on the line.

According to the invention, the field device has: an evaluation device which is suitable for carrying out a method as described above, and a data connection for connection to another measuring device for receiving measured values which relate to the other end of the line.

The invention is explained in more detail below using exemplary embodiments; in this case, by way of example:

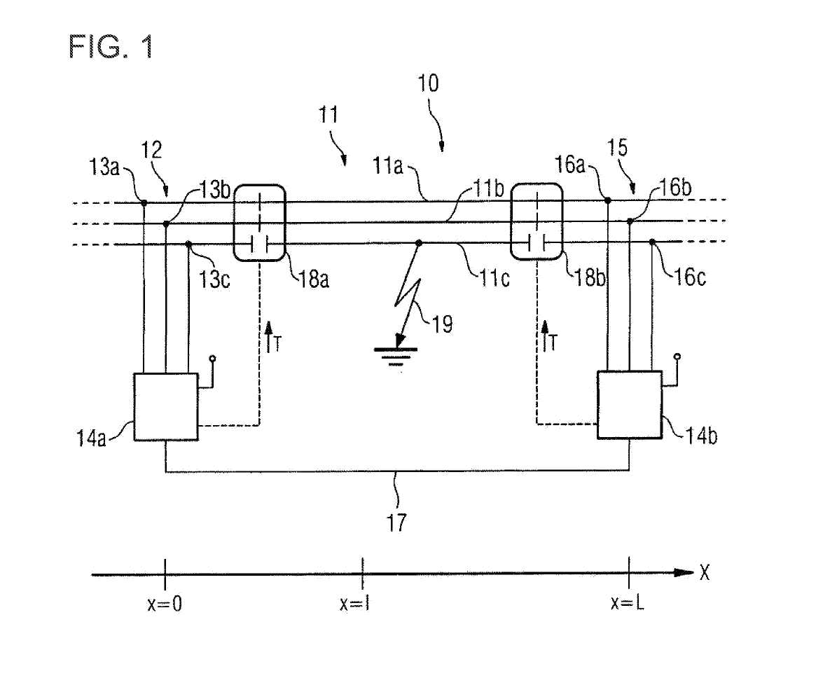

FIG. 1 shows a schematic illustration of a line section having a differential protection system, and

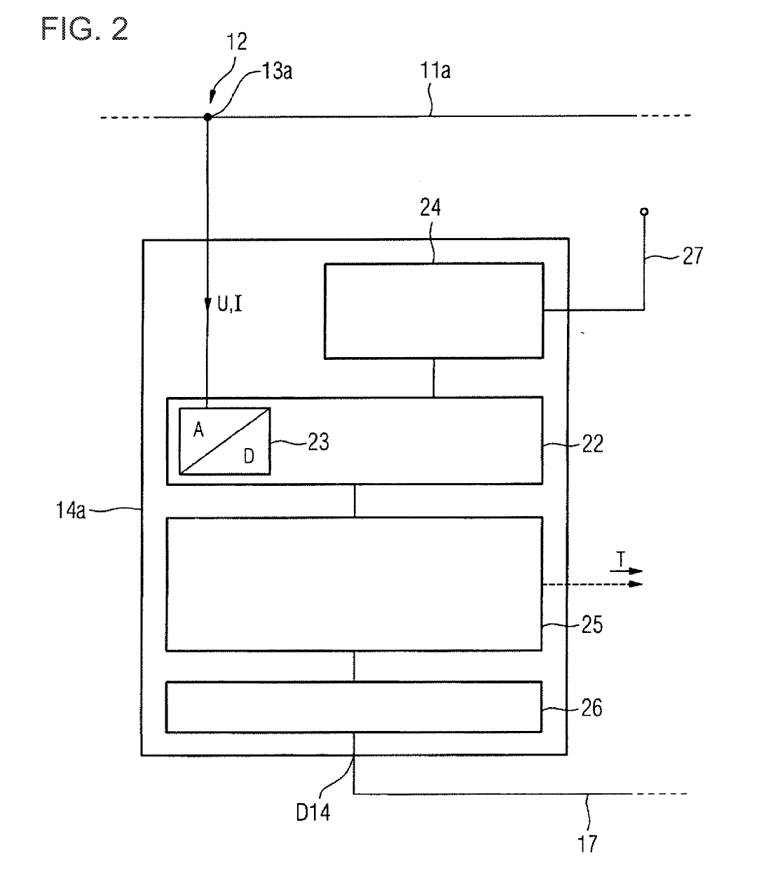

FIG. 2 shows a schematic illustration of a differential protection device.

In the figures, the same reference symbols are used for identical or comparable components for the sake of clarity.

FIG. 1 shows a differential protection system 10 which is arranged in a line section 11 of a three-phase electrical power supply line (otherwise not illustrated in any more detail). Although the line section 11 in FIG. 1 is illustrated as a line section having two ends for the sake of simplicity, it may also be a line section having three or more ends. The method described below can be accordingly applied to a line section having more than two ends.

The line section 11 shown in FIG. 1 comprises, as a three-phase line section, individual phases 11a, 11b and 11c. At a first end 12 of the line section 11, the currents flowing in the conductor phases 11a, 11b and 11c and the voltages applied to the conductor phases are measured at a first point x=0 using primary transformers 13a, 13b and 13c (not illustrated in any more detail) and are supplied to a first differential protection device 14a. At a second end 15 of the line section 11, the currents flowing in the individual conductor phases 11a, 11b and 11c and the voltages applied to the conductor phases are correspondingly recorded at a second point x=L using primary transformers 16a, 16b and 16c and are supplied to a second differential protection device 14b.

During normal operation, the differential protection devices 14a and 14b monitor the line section 11 for faults which possibly occur, for example short circuits. For this purpose, the differential protection devices 14a and 14b transmit the measured values recorded by them via a communication path 17 present between them. The communication path 17 may be either cable-based or wireless. Copper lines or optical waveguides are usually used as the communication path 17. The differential protection devices 14a and 14b use their own measured values and the measured values received from the other end to check whether there is a fault in the line section 11 of the power transmission line by means of a subtraction (explained in detail further below).

In the exemplary embodiment according to FIG. 1, the two differential protection devices 14a and 14b each have two operating modes, namely a first operating mode for a short line section 11 or a short distance between the first point x=0 and the second point x=L and a second operating mode for a long line section or a large distance between the first point x=0 and the second point x=L.

In the first operating mode for a short line section, each differential protection device 14a and 14b checks whether the difference between its own measured values and the received measured values exceeds a tripping threshold and, in the event of said threshold being exceeded, emits a trip signal (tripping signal) T as a fault signal to a circuit-breaker 18a and 18b respectively assigned to it. If the measured values for each phase are individually recorded and transmitted, this also makes it possible to clearly determine the faulty phase. The trip signal T causes the respective circuit-breaker 18a and 18b to open its switching contacts assigned to the respective faulty phase in order to thus isolate the faulty phase from the electrical power transmission line.

FIG. 1 depicts, for example, a short circuit 19 between the phase 11c of the line section 11 and ground; the circuit-breakers 18a and 18b have respectively opened their switching contacts belonging to the affected phase 11c in order to isolate the phase 11c from the electrical power transmission line.

In the differential protection devices 14a and 14b, the current measured values recorded by the primary transformers 13a, 13b, 13c and 16a, 16b, 16c may be converted, for example, into current vector measured values which allow a statement to be made on the amplitude and phase angle of the current flowing at the respective end 12 and 15. For this purpose, the current vector measured values are annotated in the complex representation, for example. The following vector measured values are recorded, for example, for the end 12 of the line section 11:

I_{0A1}·e^{-jωt}^{_{0A1}},

I_{0A2}·e^{-jωt}^{_{0A2}},

and

I_{0A3}·e^{-jωt}^{_{0A3}},

where I_{0A1} denotes the amplitude of the phase 11a, I_{0A2} denotes the amplitude of the phase 11b and I_{0A3} denotes the amplitude of the phase 11c in each case at the end 12 of the line section. In a corresponding manner, ωt_{0A1} represents the phase angle of the current in phase 11a, ωt_{0A2} represents the phase angle of the current in phase 11b and ωt_{0A3} represents the phrase angle of the current in phase 11c. The recorded current vectors for the second end 15 of the line section 11 can be an annotated in a corresponding manner as follows:

I_{0B1}·e^{-jωt}^{_{0B1}},

I_{0B2}·e^{-jωt}^{_{0B2}},

and

I_{0B3}·e^{-jωt}^{_{0B3}},

where the index “B” respectively indicates the second end 15.

The transmission of the current vector measured values and the comparison in the respective differential protection devices 14a and 14b can likewise be carried out in the vector annotation. In order to compare the current vector measured values recorded at the same time with one another in each case, a time stamp which indicates their recording time is assigned to the current vector measured values in the differential protection device 14a and 14b which respectively records. As a result of a time stamp being allocated, the demands imposed on the communication path 17 between the differential protection devices 14a and 14b are also reduced since all current vector measured values recorded at the same time can be assigned to one another using their time stamps without the need to transmit real-time data.

The above-described first operating mode of the two differential protection devices 14a and 14b is relatively accurate and reliable in the case of short distances between the differential protection devices. However, measurement errors may occur under certain circumstances in the case of larger distances between the differential protection devices because comparison values which relate to different points on the line, namely to the points x=0 and x=L, are used. The first operating mode should therefore preferably be selected only as long as the following applies:

$$L << λ / 10 = \frac{c}{10 * v} = \frac{3 * {10}^{8} m / s}{10 * 50 / s} = 60 km$$

For cables, this value is preferably reduced by the factor of the dielectric constant of the cable insulation (approx. 5). The limit in cable networks is thus approximately 12 km.

In order to also be able to reliably generate fault signals in the case of larger distances between the differential protection devices, the two differential protection devices 14a and 14b have, according to FIG. 1, at least one second operating mode instead of or in addition to the first operating mode described, which second operating mode can be selected by the user in the case of larger distances and is preset as standard on account of its higher degree of accuracy.

As also explained in detail further below, the second operating mode differs from the first operating mode in that the comparison values used to generate the fault signal relate to the same point on the line. The point selected for this purpose is arbitrary in principle, with the result that the point is referred to as the freely selectable point xw for short below.

The selectable point xw may be, for example, at the point x=0, at the point x=L, between said points or else outside the line section 11. It is assumed by way of example below that the following applies to the selectable point xw:

xw=l

where l can, in principle, assume any value between −∞ and +∞ but is preferably between 0 and L; that is to say the following preferably applies:

0≦l≦L.

In a first exemplary embodiment of the second operating mode, provision is made for comparison current values VI1 and VI2 which relate to the selectable location xw=1 to be formed as comparison values. The first and second comparison current values are determined, for example, according to:

VI1=(1/Z)*sin h(γ*l)*Ua+cos h(γ*l)*Ia

VI2=(1/Z)*sin h(γ*(L−l))*Ub+cos h(γ*(L−l))*Ib

where Z denotes the characteristic impedance of the line, γ denotes the propagation constant on the line, L denotes the length of the line, l denotes the length of the line between the selectable location and the first point x=0, Ua denotes the voltage measured value for one phase of the line recorded at the first point x=0, Ia denotes the current measured value for this phase recorded at the first point x=0, Ub denotes the voltage measured value for this phase recorded at the second point x=L, Ib denotes the current measured value for this phase recorded at the second point x=L, VI1 denotes the first comparison current value and VI2 denotes the second comparison current value.

The comparison current values are each determined and evaluated individually in terms of phase.

The propagation constant γ, the characteristic impedance Z and/or the length of the line L are determined, for example during a parameter learning phase during which no fault occurs or is allowed to occur in the line section 11, using an estimation method, the magnitude and the phase of the propagation constant, the characteristic impedance of the line and/or the length of the line L being adapted during the estimation method in such a manner that the difference between the first comparison value and the second comparison value is minimal. A least-squares estimation method, a Kalman filter algorithm or an ARMAX estimation method can be used, for example, as the estimation method. Alternatively, the two parameters for the propagation constant γ and the characteristic impedance Z can also be determined at the user end during a parameterization step using theoretically determined or measured values.

After the two comparison current values VI1 and VI2 have been determined, they are subtracted so as to form a difference value D according to:

D=|VI1−VI2|.

If this difference value satisfies a predefined tripping condition, for example is inside or outside a predefined triggering area of a difference value triggering diagram or simply exceeds a predefined maximum value, the fault or trip signal T is generated for the respective phase of the line.

In a second exemplary embodiment of the second operating mode, provision is made for comparison voltage values VU1 and VU2 which relate to the selectable location xw=l to be formed as comparison values. The first and second comparison voltage values VU1 and VU2 are determined, for example, according to:

VU1=Ua*cos h(γ*l)+Z*Ia sin h(γ*l)

VU2=Ub*cos h(γ*(L−l))+Z*Ib sin h(γ*(L−l)).

After the two comparison voltage values VU1 and VU2 have been determined, they are subtracted so as to form a difference value D according to:

D=|VU1−VU2|.

If this difference value satisfies a predefined tripping condition for one or more phases of the line, for example is inside or outside a predefined tripping area of a difference value tripping diagram or exceeds a predefined maximum value, the fault or trip signal T is generated for the phase affected in each case.

FIG. 2 shows, by way of example, the differential protection device 14a in a detailed illustration.

The differential protection device 14a has a measured value recording device 22 which contains an A/D converter 23 and is connected to the line section 11 and receives respective current and voltage measured values U and I for each phase. For the sake of clarity, the differential protection device 14a in the illustration according to FIG. 2 is only connected to the phase 11a at the end 12 of the line section 11; the recording of measured values for the remaining phases 11b and 11c is not shown in FIG. 2 but is carried out in a corresponding manner.

The differential protection device 14a also has an internal timer 24 which is synchronized with the internal timers of other differential protection devices—in particular of the differential protection device 14b—via an external time signal. The external time signal may be, for example, a time signal which is derived from a GPS signal received using an antenna 27. Another example of an external timer is a timing clock of a so-called “real-time Ethernet network”; in this case, a corresponding Ethernet interface via which the device can also communicate in the network is provided instead of the antenna 27.

The internal timer 24 passes a time signal to the measured value recording device 22 which assigns a time stamp to each recorded voltage and current measured value, which time stamp indicates that time at which the respective measured value was recorded.

The respective measured value, including its time stamp, is supplied to an evaluation device, for example in the form of a data processing device 25. The data processing device 25 is connected to a communication device 26 which is in turn connected to the communication path 17 via a data connection D14 of the differential protection device 14a in order to transmit the measured values recorded in the differential protection device 14a, including their time stamps, via the communication path 17 and to receive measured values recorded using the differential protection device 14b.

In the data processing device 25, a decision regarding whether there is a short circuit in the phase 11a of the line section 11 or in another phase of the line section 11 is made in the manner already described by comparing the measured values recorded in the first differential protection device 14a with those transmitted from the second differential protection device 14b. If appropriate, a trip signal T is generated and emitted to the circuit-breaker 18a (not illustrated in FIG. 2).

1-19. (canceled)

20. A method for generating a fault signal indicating a ground fault on a conductor line between two ends of the line, the method which comprises:
determining a first comparison value for a selectable location on the line using at least one current measured value and one voltage measured value recorded at one end of the line at a predefined measuring time, the first comparison value indicating a current that should flow or a voltage that should be present at the selectable location in a fault-free state;
determining a second comparison value for the selectable location on the line using at least one current measured value or voltage measured value recorded at an opposite end of the line at the predefined measuring time, the second comparison value indicating a current that should flow or a voltage that should be present at the selectable location in the fault-free state; and
forming a difference value between the first and second comparison values, and generating the fault signal if the difference value satisfies a predefined tripping condition.

21. The method according to claim 20, which comprises:
if a location between the two ends of the line is selected as the selectable location, determining the second comparison value using the current measured value recorded at the opposite end of the line and the voltage measured value recorded at the opposite end of the line at the predefined measuring time; and
if the opposite end of the line is selected as the selectable location, using the current measured value or voltage measured value at the opposite end of the line as the second comparison value.

22. The method according to claim 20, which comprises determining the first and second comparison values taking into account the telegraph equation that describes a propagation of electromagnetic waves on conductor lines.

23. The method according to claim 22, which comprises determining a propagation constant and a characteristic impedance of the line in a fault-free parameter learning phase in order to use the telegraph equation.

24. The method according to claim 23, wherein the propagation constant and the characteristic impedance are determined during the parameter learning phase using an estimation method, a magnitude and a phase of the propagation constant and of the characteristic impedance of the line being adapted during the estimation method in such a manner that a difference between the first comparison value and the second comparison value is at a minimum.

25. The method according to claim 24, wherein a least-squares estimation method, a Kalman filter algorithm, or an ARMAX estimation method is used as the estimation method.

26. The method according to claim 20, which comprises selecting the opposite end of the line as the selectable location.

27. The method according to claim 26, which comprises determining the first and second comparison values according to:
VI1=(1/Z)*sin h(γ*L)*Ua+cos h(γ*L)*Ia;
VI2Ib;
where Z denotes a characteristic impedance of the line, γ denotes a propagation constant on the line, L denotes a length of the line, Ua denotes the voltage measured value recorded at one end of the line, Ia denotes the current measured value recorded at one end of the line, Ib denotes the current measured value recorded at the opposite end of the line, VI1 denotes the first comparison value, and VI2 denotes the second comparison value.

28. The method according to claim 26, which comprises determining the first and second comparison values according to:
VU1=Ua*cos h(γ*L)+Z*Ia sin h(γ*L);
VU2=Ub;
where Z denotes a characteristic impedance of the line, γ denotes a propagation constant on the line, L denotes a length of the line, Ua denotes the voltage measured value recorded at one end of the line, Ia denotes the current measured value recorded at one end of the line, Ub denotes the voltage measured value recorded at the opposite end of the line, VU1 denotes the first comparison value, and VU2 denotes the second comparison value.

29. The method according to claim 20, which comprises selecting a location between the one end of the line and the opposite end of the line as the selectable location.

30. The method according to claim 29, which comprises determining the first and second comparison values according to:
VI1=(1/Z)*sin h(γ*l)*Ua+cos h(γ*l)*Ia;
VI2=(1/Z)*sin h(γ*(L−l))*Ub+cos h(γ*(L−l))*Ib;
where Z denotes a characteristic impedance of the line, γ denotes a propagation constant on the line, L denotes a length of the line, l denotes a length of the line between the selectable location and the one end of the line, Ua denotes the voltage measured value recorded at the one end of the line, Ia denotes the current measured value recorded at the one end of the line, Ub denotes the voltage measured value recorded at the opposite end of the line, Ib denotes the current measured value recorded at the opposite end of the line, VI1 denotes the first comparison value, and VI2 denotes the second comparison value.

31. The method according to claim 29, which comprises determining the first and second comparison values according to:
VU1=Ua*cos h(γ*l)+Z*Ia sin h(γ*l);
VU2=Ub*cos h(γ*(L−l))+Z*Ib sin h(γ*(L−l));
where Z denotes a characteristic impedance of the line, γ denotes a propagation constant on the line, L denotes a length of the line, l denotes a length of the line between the selectable location and the one end of the line, Ua denotes the voltage measured value recorded at the one end of the line, Ia denotes the current measured value recorded at the one end of the line, Ub denotes the voltage measured value recorded at the opposite end of the line, Ib denotes the current measured value recorded at the opposite end of the line, VU1 denotes the first comparison value, and VU2 denotes the second comparison value.

32. The method according to claim 20, which comprises measuring the current and voltage at the two ends of the line in a synchronized manner.

33. The method according to claim 20, which comprises:
measuring the current and voltage measured values at the two ends of the line in an unsynchronized manner;
providing the current and voltage measured values with a time stamp which indicates the respective recording time of the measured values; and
computationally synchronizing the current and voltage measured values of the two ends of the line using their respective recording time, and forming current and voltage measured values based on the predefined measuring time.

34. A configuration for generating a fault signal that indicates a ground fault on a conductor line between a first end of the line and a second end of the line, the configuration comprising:
a first measuring device at the first end of the line for acquiring a measured value;
a second measuring device at the second end of the line for acquiring a measured value; and
an evaluation device connected to said first and second measuring devices, said evaluation device being configured to carry out the method according to claim 20 using the measured values from said first and second measuring devices.

35. The configuration according to claim 34, wherein said evaluation device comprises a programmed data processing system.

36. The configuration according to claim 34, wherein said evaluation device is disposed in a central device, and said first and second measuring devices are connected to said central device.

37. The configuration according to claim 34, wherein said evaluation device is implemented in one of said first and second measuring devices.

38. A field device, comprising:
connections for connecting to one end of an electrical line;
an evaluation device configured for carrying out the method according to claim 20 for detecting a ground fault on the line; and
a data connection for connecting to another measuring device for receiving measured values that relate to an opposite end of the line.

39. The field device according to claim 38 configured as a protection device.
